(19) United States
(12) Patent Application Publication
(10) Pub. No.: US 2025/0151585 A1
(43) Pub. Date: May 8, 2025

(54) DISPLAY DEVICE AND MANUFACTURING METHOD THEREOF

(71) Applicant: Samsung Display Co., LTD., Yongin-si (KR)

(72) Inventors: Jin Su BYUN, Yongin-si (KR); Si Kwang KIM, Yongin-si (KR); In Young JUNG, Yongin-si (KR); Gi Heon CHOI, Yongin-si (KR)

(21) Appl. No.: 18/669,283

(22) Filed: May 20, 2024

(30) Foreign Application Priority Data
Nov. 7, 2023 (KR) 10-2023-0152681

(51) Int. Cl. H10K 59/80; H10K 59/12

(52) U.S. Cl. CPC H10K 59/879; H10K 59/1201; H10K 59/8792

(57) ABSTRACT

A display device includes a display panel, a window above the display panel, and a light control layer between the display panel and the window, and including light-blocking members spaced apart from each other, a first refractive layer on side surfaces of the light-blocking members to expose upper surfaces of the light-blocking members, and a second refractive layer on the first refractive layer, and having a refractive index that is greater than a refractive index of the first refractive layer.

### CROSS-REFERENCE TO RELATED APPLICATION

The present application claims priority to, and the benefit, of Korean Patent Application No. 10-2023-0152681, filed on Nov. 7, 2023, in the Korean Intellectual Property Office, the entire disclosure of which is incorporated herein by reference.

### BACKGROUND

### 1. Field

This disclosure relates to a display device, and a manufacturing method thereof.

### 2. Description of the Related Art

A display device may include a display panel that displays an image, a window located on (as used herein, “on” may mean “above”) the display panel, and a function panel interposed between the display panel and the window to receive a touch input or prevent a reflection of external light.

The display panel includes a light-emitting element, and light emitted from the light-emitting element may pass through the function panel and the window, and may be emitted toward a front surface of the display device.

At this time, as the technology develops, cars that go beyond simple transportation may include various display devices. Through the display device, the driver may obtain various information, including real-time traffic information and a status of the car.

However, when the light emitted from the display device is reflected from the front glass of the car, the driver's vision may be obstructed. To reduce or prevent visual obstruction, a light control film that can limit an exit angle of the light emitted from the display device may be used.

The content described above is only intended to help understand the background, and therefore should not be understood as content corresponding to prior art known to those skilled in the art of the present disclosure.

### SUMMARY

The present disclosure provides a display device, and a manufacturing method of the display device, which may reduce or prevent unintended output of light, and may improve the light output efficiency using a light control layer.

A display device according to embodiments of the present disclosure includes a display panel, a window above the display panel, and a light control layer between the display panel and the window, and including light-blocking members spaced apart from each other, a first refractive layer on side surfaces of the light-blocking members to expose upper surfaces of the light-blocking members, and a second refractive layer on the first refractive layer, and having a refractive index that is greater than a refractive index of the first refractive layer.

The light-blocking members may have a trapezoidal shape in cross section view.

An inclination angle between the first refractive layer and a plane on which the display panel is located may be about 70 degrees or more and about 89 degrees or less.

The inclination angle may correspond to the refractive index of the first refractive layer and to the refractive index of the second refractive layer.

The first refractive layer may include an inorganic material, wherein the second refractive layer includes an organic material.

The first refractive layer may include at least one of LiF or MgF.

The display device may further include a light-blocking layer between one of the light-blocking members and the first refractive layer.

A refractive index of the light-blocking layer may be greater than a refractive index of the light-blocking members, and is less than the refractive index of the first refractive layer.

The light-blocking members may have an inverted trapezoidal shape in cross section view.

The display device may further include an input-sensing layer between the display panel and the light control layer.

Another aspect of the present disclosure relates to a manufacturing method of a display device. A manufacturing method of a display device according to embodiments of the present disclosure includes providing a display panel, forming a light control layer above the display panel, and locating a window above the light control layer, wherein the forming the light control layer includes arranging light-blocking members spaced apart from each other, forming a first refractive layer on the light-blocking members, and arranging a second refractive layer, which has a refractive index that is greater than a refractive index of the first refractive layer, on the first refractive layer.

The light-blocking members may have a trapezoidal shape in cross section view, wherein an inclination angle between the first refractive layer and a plane on which the display panel is located is about 70 degrees or more and about 89 degrees or less.

The forming the light control layer may further include exposing upper surfaces of the light-blocking members.

Exposing the upper surfaces of the light-blocking members may include an etching process.

Forming the first refractive layer may include an evaporation process, wherein the first refractive layer includes an organic material.

The forming the light control layer may further include forming a light-blocking layer between one of the light-blocking members and the first refractive layer.

The light-blocking members may have an inverted trapezoidal shape in cross section view.

A manufacturing method of a display device according to one or more embodiments of the present disclosure includes providing a display panel forming a light control layer above the display panel, and arranging a window above the light control layer, wherein the forming the light control layer includes forming a first refractive layer on the display panel, etching the first refractive layer to expose the display panel, arranging light-blocking members filling the etched first refractive layer, and arranging a second refractive layer, which has a refractive index that is greater than a refractive index of the first refractive layer, on the first refractive layer.

The first refractive layer may include a plurality of protrusions having a trapezoidal shape.

The light-blocking members may have an inverted trapezoidal shape in cross section view.

A display device according to embodiments of the present disclosure can reduce or prevent unintended output of light, and can improve the light output efficiency of the display device.

Effects according to embodiments are not limited by contents exemplified above, and more various effects are included in the present specification.

### BRIEF DESCRIPTION OF THE DRAWINGS

FIG. 1 is a drawing showing a display device according to embodiments of the present disclosure.

FIG. 2 is a cross-sectional view showing one or more embodiments of a display device taken along the line I-I′ of FIG. 1.

FIG. 3 is a cross-sectional view showing an example of a light control layer of FIG. 2.

FIG. 4 is a drawing showing a luminance ratio of lights output to a front surface of a display device depending on an inclination angle of a first refractive layer of FIG. 3.

FIG. 5 is a cross-sectional view showing one or more embodiments of a display device taken along the line I-I′ of FIG. 1.

FIG. 6 is a cross-sectional view showing one or more embodiments of a display device taken along the line I-I′ of FIG. 1.

FIG. 7 is a flowchart showing a manufacturing method of a display device according to one or more embodiments of the present disclosure.

FIG. 8 is a flowchart showing one or more embodiments of an operation S720 of FIG. 7.

FIGS. 9 to 12 are schematic cross-sectional views showing each manufacturing operation of a manufacturing method of a display device according to one or more embodiments.

FIG. 13 is a flowchart showing one or more embodiments of an operation S720 of FIG. 7.

FIGS. 14 to 16 are schematic cross-sectional views showing each manufacturing operation of a manufacturing method of a display device according to one or more embodiments.

### DETAILED DESCRIPTION

Aspects of some embodiments of the present disclosure and methods of accomplishing the same may be understood more readily by reference to the detailed description of embodiments and the accompanying drawings. The described embodiments are provided as examples so that this disclosure will be thorough and complete, and will fully convey the aspects of the present disclosure to those skilled in the art. Accordingly, processes, elements, and techniques that are redundant, that are unrelated or irrelevant to the description of the embodiments, or that are not necessary to those having ordinary skill in the art for a complete understanding of the aspects of the present disclosure may be omitted. Unless otherwise noted, like reference numerals, characters, or combinations thereof denote like elements throughout the attached drawings and the written description, and thus, repeated descriptions thereof may be omitted.

The described embodiments may have various modifications and may be embodied in different forms, and should not be construed as being limited to only the illustrated embodiments herein. The use of “can,” “may,” or “may not” in describing an embodiment corresponds to one or more embodiments of the present disclosure. The present disclosure covers all modifications, equivalents, and replacements within the idea and technical scope of the present disclosure. Further, each of the features of the various embodiments of the present disclosure may be combined with each other, in part or in whole, and technically various interlocking and driving are possible. Each embodiment may be implemented independently of each other or may be implemented together in an association.

In the drawings, the relative sizes of elements, layers, and regions may be exaggerated for clarity and/or descriptive purposes. Additionally, the use of cross-hatching and/or shading in the accompanying drawings is generally provided to clarify boundaries between adjacent elements. As such, neither the presence nor the absence of cross-hatching or shading conveys or indicates any preference or requirement for particular materials, material properties, dimensions, proportions, commonalities between illustrated elements, and/or any other characteristic, attribute, property, etc., of the elements, unless specified.

Various embodiments are described herein with reference to sectional illustrations that are schematic illustrations of embodiments and/or intermediate structures. As such, variations from the shapes of the illustrations as a result of, for example, manufacturing techniques and/or tolerances, are to be expected. Further, specific structural or functional descriptions disclosed herein are merely illustrative for the purpose of describing embodiments according to the concept of the present disclosure. Thus, embodiments disclosed herein should not be construed as limited to the illustrated shapes of elements, layers, or regions, but are to include deviations in shapes that result from, for instance, manufacturing.

For example, an implanted region illustrated as a rectangle will, typically, have rounded or curved features and/or a gradient of implant concentration at its edges rather than a binary change from implanted to non-implanted region. Likewise, a buried region formed by implantation may result in some implantation in the region between the buried region and the surface through which the implantation takes place.

Spatially relative terms, such as “beneath,” “below,” “lower,” “lower side,” “under,” “above,” “upper,” “upper side,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below,” “beneath,” “or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly. Similarly, when a first part is described as being arranged “on” a second part, this indicates that the first part is arranged at an upper side or a lower side of the second part without the limitation to the upper side thereof on the basis of the gravity direction.

Further, the phrase “in a schematic cross-sectional view” means when a schematic cross-section taken by vertically cutting an object portion is viewed from the side. The terms “face” and “facing” may mean that a first object may directly or indirectly oppose a second object. In a case in which a third object intervenes between a first and second object, the first and second objects may be understood as being indirectly opposed to one another, although still facing each other.

It will be understood that when an element, layer, region, or component is referred to as being “formed on,” “on,” “connected to,” or “(operatively or communicatively) coupled to” another element, layer, region, or component, it can be directly formed on, on, connected to, or coupled to the other element, layer, region, or component, or indirectly formed on, on, connected to, or coupled to the other element, layer, region, or component such that one or more intervening elements, layers, regions, or components may be present. In addition, this may collectively mean a direct or indirect coupling or connection and an integral or non-integral coupling or connection. For example, when a layer, region, or component is referred to as being “electrically connected” or “electrically coupled” to another layer, region, or component, it can be directly electrically connected or coupled to the other layer, region, and/or component or one or more intervening layers, regions, or components may be present. The one or more intervening components may include a switch, a resistor, a capacitor, and/or the like. In describing embodiments, an expression of connection indicates electrical connection unless explicitly described to be direct connection, and “directly connected/directly coupled,” or “directly on,” refers to one component directly connecting or coupling another component, or being on another component, without an intermediate component.

In addition, in the present specification, when a portion of a layer, a film, an area, a plate, or the like is formed on another portion, a forming direction is not limited to an upper direction but includes forming the portion on a side surface or in a lower direction. On the contrary, when a portion of a layer, a film, an area, a plate, or the like is formed “under” another portion, this includes not only a case where the portion is “directly beneath” another portion but also a case where there is further another portion between the portion and another portion. Meanwhile, other expressions describing relationships between components, such as “between,” “immediately between” or “adjacent to” and “directly adjacent to,” may be construed similarly. It will be understood that when an element or layer is referred to as being “between” two elements or layers, it can be the only element or layer between the two elements or layers, or one or more intervening elements or layers may also be present.

For the purposes of this disclosure, expressions such as “at least one of,” or “any one of,” or “one or more of” when preceding a list of elements, modify the entire list of elements and do not modify the individual elements of the list. For example, “at least one of X, Y, and Z,” “at least one of X, Y, or Z,” “at least one selected from the group consisting of X, Y, and Z,” and “at least one selected from the group consisting of X, Y, or Z” may be construed as X only, Y only, Z only, any combination of two or more of X, Y, and Z, such as, for instance, XYZ, XYY, YZ, and ZZ, or any variation thereof. Similarly, the expressions “at least one of A and B” and “at least one of A or B” may include A, B, or A and B. As used herein, “or” generally means “and/or,” and the term “and/or” includes any and all combinations of one or more of the associated listed items. For example, the expression “A and/or B” may include A, B, or A and B. Similarly, expressions such as “at least one of,” “a plurality of,” “one of,” and other prepositional phrases, when preceding a list of elements, modify the entire list of elements and do not modify the individual elements of the list.

It will be understood that, although the terms “first,” “second,” “third,” etc., may be used herein to describe various elements, components, regions, layers and/or sections, these elements, components, regions, layers and/or sections should not be limited by these terms. These terms do not correspond to a particular order, position, or superiority, and are used only used to distinguish one element, member, component, region, area, layer, section, or portion from another element, member, component, region, area, layer, section, or portion. Thus, a first element, component, region, layer or section described below could be termed a second element, component, region, layer or section, without departing from the spirit and scope of the present disclosure. The description of an element as a “first” element may not require or imply the presence of a second element or other elements. The terms “first,” “second,” etc. may also be used herein to differentiate different categories or sets of elements. For conciseness, the terms “first,” “second,” etc. may represent “first-category (or first-set),” “second-category (or second-set),” etc., respectively.

In the examples, the x-axis, the y-axis, and/or the z-axis are not limited to three axes of a rectangular coordinate system, and may be interpreted in a broader sense. For example, the x-axis, the y-axis, and the z-axis may be perpendicular to one another, or may represent different directions that are not perpendicular to one another. The same applies for first, second, and/or third directions.

The terminology used herein is for the purpose of describing embodiments only and is not intended to be limiting of the present disclosure. As used herein, the singular forms “a” and “an” are intended to include the plural forms as well, while the plural forms are also intended to include the singular forms, unless the context clearly indicates otherwise. It will be further understood that the terms “comprises,” “comprising,” “have,” “having,” “includes,” and “including,” when used in this specification, specify the presence of the stated features, integers, steps, operations, elements, and/or components, but do not preclude the presence or addition of one or more other features, integers, steps, operations, elements, components, and/or groups thereof.

When one or more embodiments may be implemented differently, a specific process order may be performed differently from the described order. For example, two consecutively described processes may be performed substantially at the same time or performed in an order opposite to the described order.

As used herein, the term “substantially,” “about,” “approximately,” and similar terms are used as terms of approximation and not as terms of degree, and are intended to account for the inherent deviations in measured or calculated values that would be recognized by those of ordinary skill in the art. For example, “substantially” may include a range of +/−5% of a corresponding value. “About” or “approximately,” as used herein, is inclusive of the stated value and means within an acceptable range of deviation for the particular value as determined by one of ordinary skill in the art, considering the measurement in question and the error associated with measurement of the particular quantity (i.e., the limitations of the measurement system). For example, “about” may mean within one or more standard deviations, or within ±30%, 20%, 10%, 5% of the stated value. Further, the use of “may” when describing embodiments of the present disclosure refers to “one or more embodiments of the present disclosure.”

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

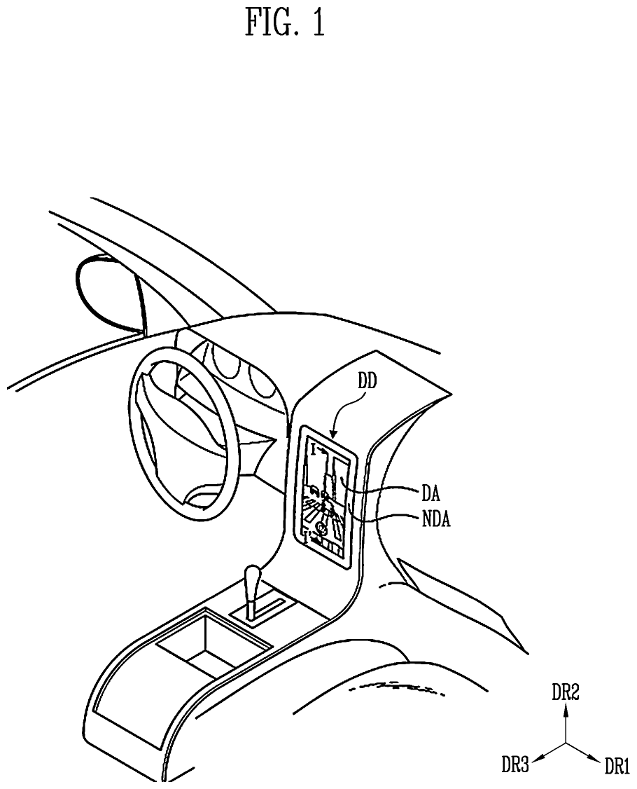

FIG. 1 is a drawing showing a display device according to embodiments of the present disclosure.

The display device DD shown in FIG. 1 may be a vehicle information display (or Center Information Display (CID)). The display device DD may be a device activated depending on an electrical signal. The display device DD may include various embodiments. For example, the display device DD may be provided to transportation means, such as a car, bicycle, motorcycle, ship, airplane, and the like. Additionally, the display device DD may be applied to large electronic devices, such as televisions, monitors, electronic signs, etc., as well as small and medium-sized electronic devices, such as tablets, navigation devices, game consoles, smart watches, etc. In addition, the display device DD may be applied to a wearable electronic device, such as a head-mount display, etc. This is an example, and it may be applied in other display devices without deviating from the concept of the present disclosure.

A display area DA and a non-display area NDA may be defined in the display device DD. The display area DA may be an area where the image IM is displayed. In FIG. 1, a traffic situation is shown as an example of an image IM. The non-display area NDA may be an area where the image IM is not displayed. The display area DA may be parallel to a plane defined by a first direction DR1, and by a second direction DR2 that intersects the first direction DR1.

In this specification, an upper surface (or front surface) and a lower surface (or back surface) of each member may be defined based on the direction in which the image IM is displayed. The upper and lower surfaces may face each other in the third direction DR3, and a normal direction of each of the upper and lower surfaces may be parallel to the third direction DR3.

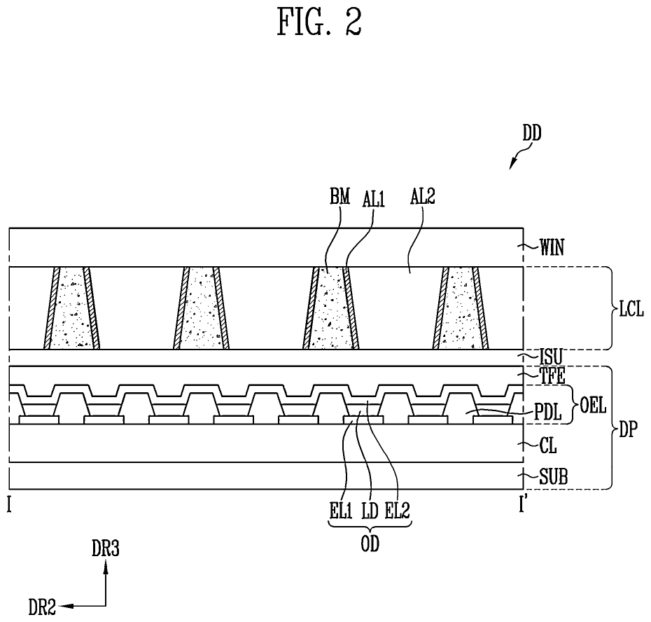

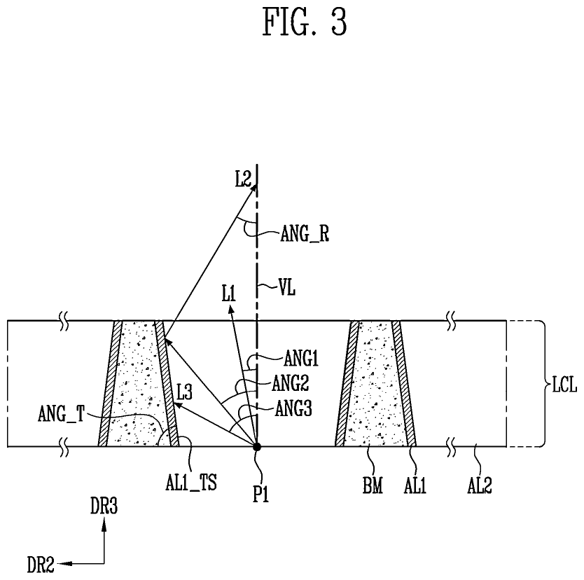

FIG. 2 is a cross-sectional view showing one or more embodiments of a display device taken along the line I-I′ of FIG. 1. FIG. 3 is a cross-sectional view showing an example of a light control layer of FIG. 2.

Referring to FIG. 2, the display device DD may include a display panel DP, an input-sensing layer ISU, a light control layer LCL, and a window WIN.

The display panel DP may include a base layer SUB, a circuit layer CL, a display element layer OEL, and an encapsulation layer TFE. In one or more embodiments of the present disclosure, the display panel DP may be an organic light-emitting display panel or a quantum dot display panel. The light-emitting layer of the organic light-emitting display panel may include an organic light-emitting material. The light-emitting layer of the quantum dot light-emitting display panel may include quantum dots, etc. However, this is an example, and the type of display panel DP is not limited thereto.

The base layer SUB may be a polymer substrate, a plastic substrate, a glass substrate, a quartz substrate, etc. The base layer SUB may be a transparent insulating substrate. The base layer SUB may be rigid. The base layer SUB may be flexible.

The circuit layer CL may be located on (as used herein, “on” may mean “above”) the base layer SUB, and the circuit layer CL may include a plurality of transistors, and each of the transistors may include a control electrode, an input electrode, and an output electrode. For example, the circuit layer CL may include a switching transistor and a driving transistor for driving the light-emitting elements OD of the display element layer OEL.

The display element layer OEL may include a plurality of light-emitting elements OD. The light-emitting elements OD may include a first electrode EL1, a functional layer LD, and a second electrode EL2, sequentially stacked. The functional layer LD may include a hole transport region, a light-emitting layer, and an electron transport region, sequentially stacked. Each of the plurality of light-emitting elements OD may emit light at different wavelength ranges. In contrast, each of the plurality of light-emitting elements OD may emit light at the same wavelength range.

A pixel-defining layer PDL may be defined in the display element layer OEL. For example, the pixel-defining layer PDL may be formed including polyacrylate-based resin or polyimide-based resin. In contrast, the pixel-defining layer PDL may be formed of an inorganic material. For example, the pixel-defining layer PDL may be formed including silicon nitride, silicon oxide, silicon oxynitride, etc. In the display element layer OEL, the light-emitting elements OD may be separated by a pixel-defining layer PDL.

The encapsulation layer TFE may be located on the display element layer OEL to seal the display element layer OEL. The encapsulation layer TFE may protect the display element layer OEL from moisture and/or oxygen, and may protect the display element layer OEL from foreign substances, such as dust particles. The encapsulation layer TFE may include at least one inorganic layer or at least one organic layer. The encapsulation layer TFE may have a structure in which organic layers and inorganic layers are alternately stacked. For example, the encapsulation layer TFE may have a structure in which an inorganic layer, an organic layer, and an inorganic layer are sequentially stacked.

According to one or more embodiments, the display device DD may further include an input-sensing layer ISU located on the display panel DP. For example, the input-sensing layer ISU may be located on the encapsulation layer TFE. The input-sensing layer ISU may sense an externally applied input. The input may be provided in various forms. For example, the external input may include various types, such as a part of the user's body, a stylus pen, light, heat, pressure, etc. Additionally, the external input may include contact with a part of the user's body, such as the user's hand, as well as touching or occupying a nearby or adjacent space (e.g., hovering).

The light control layer LCL may include light-blocking members BM, a first refractive layer AL1, and a second refractive layer AL2.

The light-blocking members BM may be located on the display panel DP or the input-sensing layer ISU. For example, the light-blocking members BM may be spaced apart from each other in the second direction DR2 on the display panel DP or the input-sensing layer ISU.

Each of the light-blocking members BM may have a trapezoidal shape in cross section view. For example, each of the light-blocking members BM may have a trapezoidal shape in cross section view, and may be spaced apart from each other.

The light-blocking members BM may block some of the light incident on the light control layer LCL. For example, the light-blocking members BM may absorb some of the light incident on the light control layer LCL, and may reduce or block the light emitted toward the window WIN and/or the user of the display device DD.

The first refractive layer AL1 may be located on (e.g., on the sides of) the light-blocking members BM. The first refractive layer AL1 may expose upper surfaces of the light-blocking members BM. For example, the first refractive layer AL1 may be located on side surfaces of the light-blocking members BM having a trapezoidal shape. Accordingly, the first refractive layer AL1 may be inclined at an angle (e.g., a certain/corresponding angle) from the plane of the display panel DP.

The first refractive layer AL1 may include an inorganic material. For example, the first refractive layer AL1 may be an inorganic layer including at least one of LiF, MgF, or SiOₙ (n being a natural number of 1 or more).

The second refractive layer AL2 may be located on the first refractive layer AL1 (e.g., on/above sides of the first refractive layer AL1). For example, the first refractive layer AL1 may be located on the light-blocking members BM, which are spaced apart (e.g., at a predetermined distance), and the second refractive layer AL2 may be located in a space defined by the first refractive layers AL spaced apart from each other.

The window WIN may be located on the light control layer LCL. For example, the window WIN may be located on the light control layer LCL to protect the upper surface of the display device DD.

According to some embodiments, an optical layer may be located between the window WIN and the light control layer LCL. Accordingly, the light control layer LCL and the window WIN may be spaced apart in some embodiments. For example, surfaces of the light-blocking members BM and the window WIN may be spaced apart from each other without contacting each other.

The window WIN may include an optically transparent insulating material. For example, the window WIN may include glass or plastic. Additionally, the window WIN may have a multi-layer structure or a single-layer structure. For example, the window WIN may include a plurality of plastic films bonded with an adhesive, or may include a glass substrate and a plastic film bonded with an adhesive.

Referring to FIGS. 2 and 3, the display panel DP may emit a plurality of lights. For example, the display panel DP may emit first to third lights L1, L2, and L3.

Each of the first to third lights L1, L2, and L3 may be incident on the light control layer LCL at an angle (e.g., predetermined angle). For example, the first to third lights L1, L2, and L3 may respectively be incident on the first point P1 of the light control layer LCL at respective incident angles ANG1, ANG2, and ANG3 based on a vertical line VL.

The first light L1 may be incident on the first point P1 at a first incident angle ANG1. The first light L1 may travel directly toward the window WIN. For example, the first light L1 may not be incident on the first refractive layer AL1.

The second light L2 may be incident on the first point P1 at a second incident angle ANG2. The second light L2 may pass through the second refractive layer AL2, and may be obliquely incident on the first refractive layer AL1. For example, the first refractive layer AL1 may have an inclined surface AL1_TS that is inclined with respect to the upper surface of the display panel DP, and the second light L2 may be incident on the inclined surface AL1_TS of the first refractive layer AL1. The inclination angle ANG_T of the inclined surface AL1_TS may be substantially equal to an angle at which the side surfaces of the light-blocking members BM are inclined with respect to the upper surface of the display panel DP. According to embodiments, the inclination angle ANG_T of the inclined surface AL1_TS of the first refractive layer AL1 may be about 70 degrees to about 89 degrees.

The second light L2 may be reflected (e.g., totally reflected) at the inclined surface AL1_TS of the first refractive layer AL1. A refractive index of the second refractive layer AL2 may be greater than a refractive index of the first refractive layer AL1. Accordingly, the inclined surface AL1_TS of the first refractive layer AL1 may form a total reflection surface in a relationship with the second refractive layer AL2, and the second light L2 may be totally reflected from the inclined surface AL1_TS of the first refractive layer AL1 (e.g., at corresponding angles) to travel straight, or directly, toward the window WIN. The reflected second light L2 may travel straight with a reflection angle ANG_R based on the vertical line VL, and the reflection angle ANG_R may be less than the second incident angle ANG2. Accordingly, the light output efficiency of the display device DD may increase, and the luminance of the image viewed by the user of the display device DD may increase.

The inclination angle ANG_T may be determined by, or may correspond to, the refractive index of the first refractive layer AL1 and the refractive index of the second refractive layer AL2. For example, a critical angle of total reflection may be determined by, or may correspond to, a difference between the refractive index of the first refractive layer AL1 and the refractive index of the second refractive layer AL2. Further, for example, the inclination angle ANG_T of the first refractive layer AL1 may be determined based on the critical angle of total reflection and the incident angle ANG2 of the second light L2 emitted from the display panel DP. That is, the inclination angle (or taper angle) of the light-blocking members BM may be determined based on the above. For example, the larger the difference between the refractive index of the first refractive layer AL1 and the refractive index of the second refractive layer AL2, the larger the inclination angle ANG_T of the first refractive layer AL1.

The third light L3 may be incident on the first point P1 at a third incident angle ANG3. The third light L3 may travel straight toward the first refractive layer AL1, and the third light L3 might be not reflected by the first refractive layer AL1, and may be absorbed by the light-blocking members BM. For example, an angle at which the third light L3 is incident on the inclined surface AL1_TS of the first refractive layer AL1 may exceed the critical angle of total reflection. Accordingly, the third light L3 may pass through the first refractive layer AL1 to be absorbed in/by the light-blocking members BM.

According to one or more embodiments of the present disclosure, the display device DD may reduce or prevent visibility of light incident on the light control layer LCL and beyond the critical angle (of total reflection) by the user of the display device DD. For example, the first refractive layer AL1 may not reflect light incident on the inclined surface AL1_TS of the first refractive layer AL1 beyond the critical angle of total reflection, and the corresponding lights may be absorbed in the light-blocking members BM. Accordingly, the display device DD may reduce or prevent unintended lights (e.g., third light L3) from being output to the front of the display device DD.

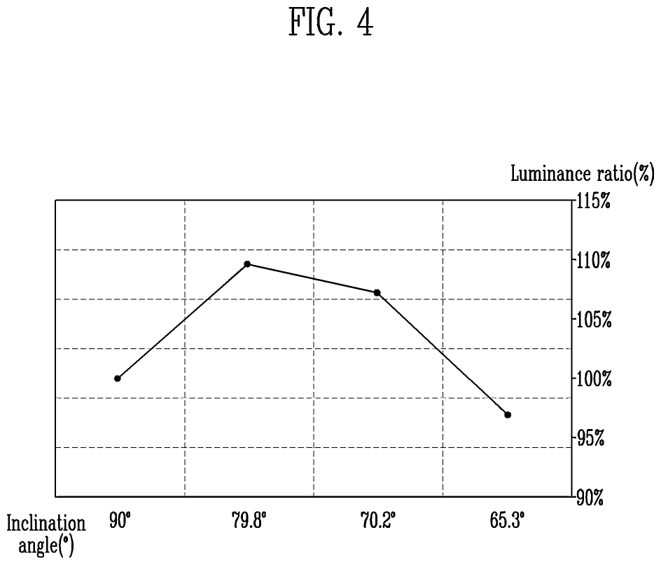

FIG. 4 is a drawing showing a luminance ratio of lights output to a front surface of a display device depending on an inclination angle of a first refractive layer of FIG. 3.

Referring to FIGS. 3 and 4, the luminance of light output from the display panel DP to the front surface of the display device DD may vary depending on the inclination angle ANG_T of the first refractive layer AL1. For example, depending on the inclination angle ANG_T of the first refractive layer AL1, the luminance of light output to the front surface of the display device DD among the first to third lights L1, L2, and L3 may vary.

The luminance of light output from the display panel DP to the front surface of the display device DD may be based on the inclination angle ANG_T of the first refractive layer AL1 being about 90 degrees. For example, when the inclination angle ANG_T of the first refractive layer AL1 is about 90 degrees, a luminance ratio of light output to the front surface of the display device DD among the first to third lights L1, L2, and L3, may be about 100%. The refractive index of the first refractive layer AL1 may be about 1.39, the second refractive layer AL2 may include an organic material, and the refractive index of the second refractive layer AL2 may be about 1.53. Additionally, the refractive index of the window WIN may be about 1.5. Additionally, the light-blocking members BM may include an organic material, and a distance at which the light-blocking members BM are spaced apart from each other may be substantially constant. For example, an angle formed between one point on a bottom side of one of the trapezoid-shaped light-blocking members BM, and another point on a top side of another light-blocking members BM adjacent thereto, from the plane on which the light control layer LCL is located, may be constant. For example, the corresponding angle may be 51.34 degrees.

If the inclination angle ANG_T of the first refractive layer AL1 is about 79.8 degrees, the luminance ratio of light output to the front surface of the display device DD, among the first to third lights L1, L2, and L3, may be about 110%. Additionally, when the inclination angle ANG_T of the first refractive layer AL1 is about 70.2 degrees, the luminance ratio of light output to the front surface of the display device DD, among the first to third lights L1, L2, and L3, may be about 107%. However, when the inclination angle ANG_T of the first refractive layer AL1 is about 65.3 degrees, the luminance ratio of light output to the front surface of the display device DD, among the first to third lights L1, L2, and L3, may be about 97%. That is, the light output efficiency of the display device DD when the inclination angle ANG_T of the first refractive layer AL1 is about 70.2 degrees or more, and about 89 degrees or less, may be relatively larger than when the inclination angle ANG_T of the first refractive layer AL1 is about 90 degrees. Accordingly, according to one or more embodiments of the present disclosure, when the inclination angle ANG_T of the first refractive layer AL1 is about 70 degrees or more, and about 89 degrees or less, the light output efficiency of the display device DD may be relatively improved.

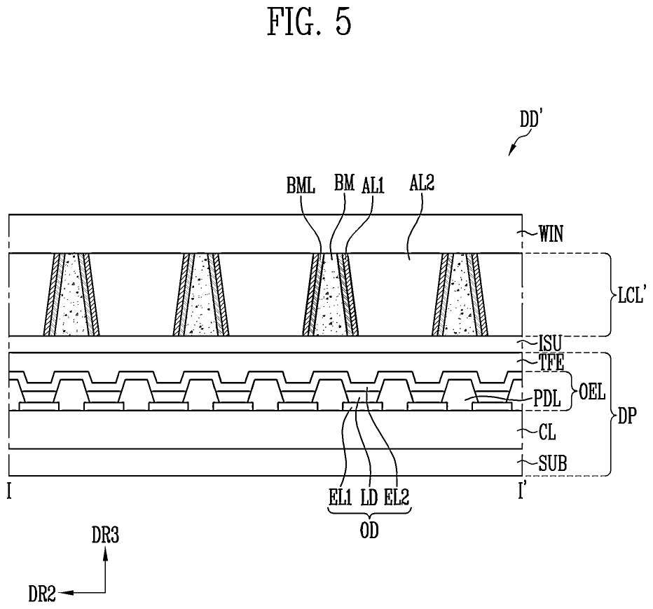

FIG. 5 is a cross-sectional view showing one or more embodiments of a display device taken along the line I-I′ of FIG. 1.

Referring to FIG. 5, the display device DD′ may include a display panel DP, an input-sensing layer ISU, a light control layer LCL′, and a window WIN.

The display panel DP, the input-sensing layer ISU, and the window WIN of FIG. 5 may be described similarly to the display panel DP, the input-sensing layer ISU, and the window WIN of FIG. 2. Hereinafter, redundant description will be omitted.

According to embodiments, an optical layer may be located between the window WIN and the light control layer LCL′. Accordingly, the light control layer LCL′ and the window WIN may be spaced apart. For example, the upper surface of the light-blocking members BM and the lower surface of the window WIN may be spaced apart from each other without contacting each other.

The light control layer LCL′ may include light-blocking members BM, a light-blocking layer BML, a first refractive layer AL1, and a second refractive layer AL2. The light-blocking members BM, the first refractive layer AL1, and the second refractive layer AL2 of FIG. 5 may be described similarly to the light-blocking members BM, the first refractive layer AL1, and the second refractive layer AL2 of FIG. 2, and hereinafter redundant descriptions will be omitted.

The light-blocking layer BML may be located on the light-blocking members BM. For example, the light-blocking layer BML may be located between any one of the light-blocking members BM and a corresponding first refractive layer AL1.

The refractive index of the light-blocking layer BML may be greater than the refractive index of the light-blocking members BM, and may be less than the refractive index of the first refractive layer AL1. Accordingly, the light-blocking layer BML can stably absorb the light to be blocked, among the light incident on the first refractive layer AL1 into the light-blocking members BM. For example, a difference between the refractive index of the first refractive layer AL1 and the light-blocking layer BML may be relatively less than a difference between the refractive index of the first refractive layer AL1 and the light-blocking members BM. Accordingly, the degree of refraction of light incident from the first refractive layer AL1 to the light-blocking layer BML may not be relatively large.

If only the first refractive layer is located on the light-blocking members, light may be directly incident from the first refractive layer to the light-blocking members, and the degree of refraction of the corresponding lights may be relatively larger than the degree of refraction of the light incident from the first refractive layer to the light-blocking layer. Some of the light may be excessively refracted to be incident toward the window without being absorbed by the light-blocking members, and the visibility of the display device may be reduced due to unintended output of light.

According to one or more embodiments of the present disclosure, when the light output from the display panel DP passes through the first refractive layer AL1, the light-blocking layer BML may allow light that is to be blocked, among the output lights, to be stably incident to the light-blocking members BM. Accordingly, visibility of the display device DD′ may be improved.

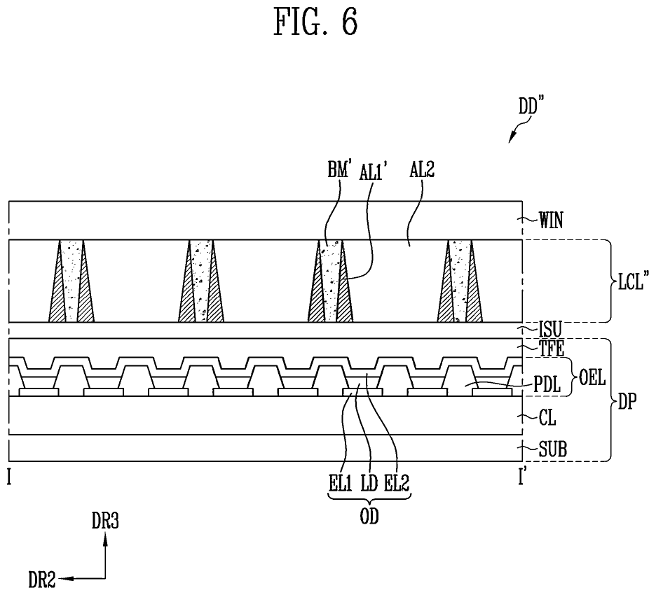

FIG. 6 is a cross-sectional view showing one or more embodiments of a display device taken along the line I-I′ of FIG. 1.

Referring to FIG. 6, the display device DD″ may include a display panel DP, an input-sensing layer ISU, a light control layer LCL″, and a window WIN.

The display panel DP, the input-sensing layer ISU, and the window WIN of FIG. 6 may be described similarly to the display panel DP, the input-sensing layer ISU, and the window WIN of FIG. 2, and redundant descriptions will be omitted.

The light control layer LCL″ may include light-blocking members BM′, a first refractive layer AL1′, and a second refractive layer AL2. The second refractive layer AL2 of FIG. 6 may be described similarly to the second refractive layer AL2 of FIG. 2, and hereinafter redundant descriptions will be omitted.

According to embodiments, an optical layer may be located between the window WIN and the light control layer LCL″. Accordingly, the light control layer LCL″ and the window WIN may be spaced apart. For example, the upper surface of the light-blocking members BM and the lower surface of the window WIN may be spaced apart from each other without contacting each other.

The light-blocking members BM′ may be located on the display panel DP or the input-sensing layer ISU. For example, the light-blocking members BM may be spaced apart from each other in the second direction DR2 on the display panel DP or the input-sensing layer ISU.

Each of the light-blocking members BM′ may have an inverted trapezoidal shape in cross section view. For example, each of the light-blocking members BM′ may have an inverted trapezoidal shape in cross section view, and may be spaced apart from each other.

The light-blocking members BM′ may block some of the light incident on the light control layer LCL″. For example, the light-blocking members BM′ may absorb some of the light incident on the light control layer LCL″, and may reduce or prevent the light emitted toward the window WIN and/or the user of the display device DD.

The first refractive layer AL1′ may include an inorganic material. For example, the first refractive layer AL1′ may be an inorganic layer including at least one of LiF, MgF, or SiOₙ (n being a natural number of 1 or more).

The first refractive layer AL1′ may be located on (e.g., on or contacting surfaces of) the light-blocking members BM′. The first refractive layer AL1′ may expose the upper surfaces of the light-blocking members BM′ (e.g., the upper surface of a light-blocking member BM′ may be surrounded by one or more first refractive layers AL1′). For example, the first refractive layer AL1′ may be located on the side surface of each of the light-blocking members BM′ having an inverted trapezoidal shape. Accordingly, the first refractive layer AL1′ may be inclined at a certain angle from the plane where the display panel DP is located. For example, the first refractive layer AL1′ may be inclined at an acute angle between the plane formed by the display panel DP and the left and right side surfaces of each of the light-blocking members BM′.

The refractive index of the second refractive layer AL2 may be greater than the refractive index of the first refractive layer AL1′. Accordingly, the inclined surface of the first refractive layer AL1′ may form a total reflection surface in relationship with the second refractive layer AL2, and some of the light incident on the first refractive layer AL1′ may be totally reflected by the inclined surface of the refractive layer AL1′. For example, lights with an incident angle exceeding the critical angle of total reflection of the first refractive layer AL1′, among the lights incident on the first refractive layer AL1′, may be totally reflected by the inclined surface of the first refractive layer AL1′.

According to one or more embodiments of the present disclosure, when the light output from the display panel DP passes through the first refractive layer AL1′, light that is to be blocked among the output lights may stably be incident on the light-blocking members BM′. For example, light that is not totally reflected, among lights incident on the side surface of the first refractive layer AL1′, may be refracted by the first refractive layer AL1′. The refracted light may be incident on the light-blocking members BM′ having an inverted trapezoidal shape to be stably absorbed by the light-blocking members BM′. Therefore, when the light output from the display panel DP passes through the first refractive layer AL1′, the light-blocking members BM′ may reduce or prevent the light that is to be blocked from being unintentionally visible to the user of the display device DD.

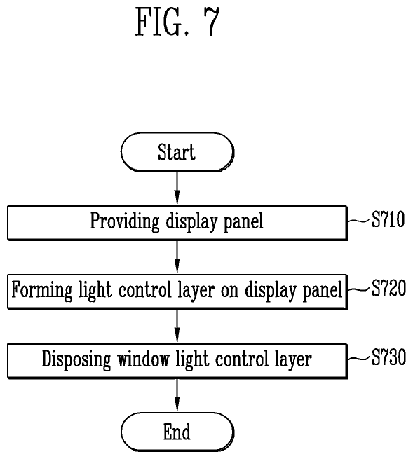

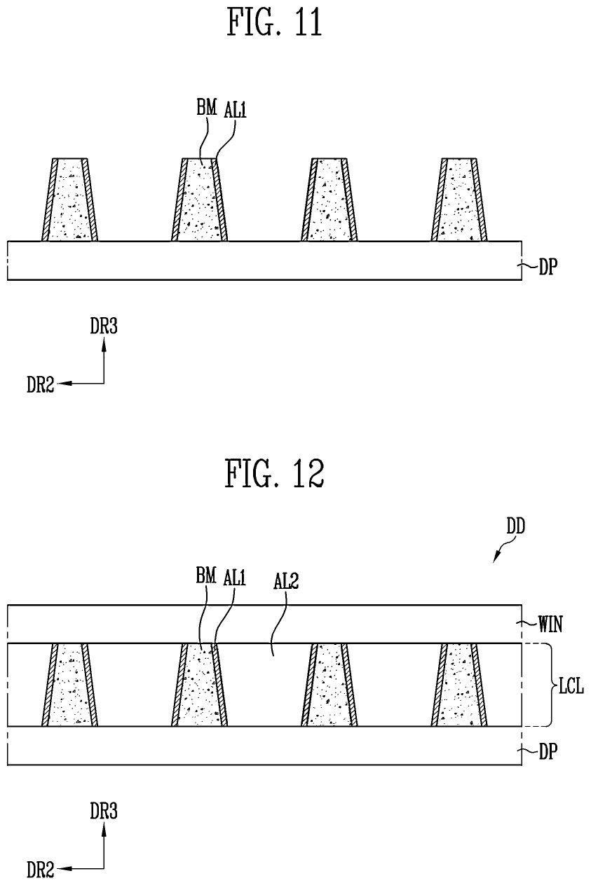

Next, a manufacturing method of a display device according to one or more embodiments will be described with reference to FIGS. 7 to 12. Duplicate description is briefly explained or not repeated.

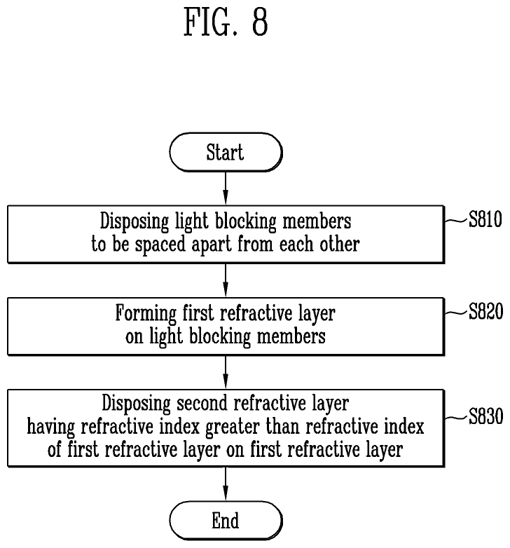

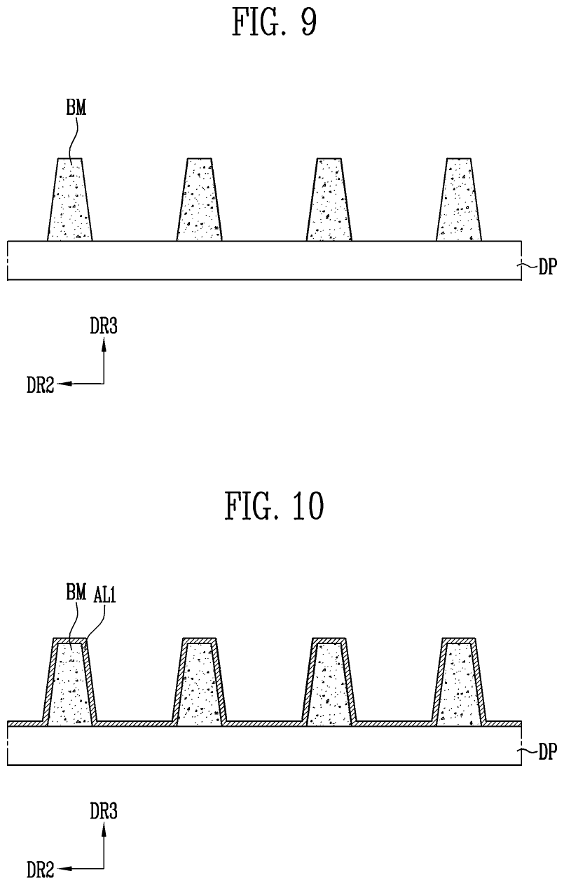

FIG. 7 is a flowchart showing a manufacturing method of a display device according to one or more embodiments of the present disclosure. FIG. 8 is a flowchart showing one or more embodiments of an operation S720 of FIG. 7. FIGS. 9 to 12 are schematic cross-sectional views showing each manufacturing operation of a manufacturing method of a display device according to one or more embodiments.

Referring to FIG. 7, the manufacturing method of the display device DD according to one or more embodiments of the present disclosure includes providing a display panel (S710), forming a light control layer on the display panel (S720), and disposing (e.g., locating or arranging) a window on the light control layer (S730).

Referring to FIGS. 2, 7, and 9, in S710, the display panel DP may be provided. For example, the display panel DP, in which a base layer SUB, a circuit layer CL, a display element layer OEL, and an encapsulation layer TFE are sequentially stacked, may be provided. According to embodiments, the input-sensing layer ISU may be located on the display panel DP.

Referring to FIGS. 2 and 7 to 12, in an operation S720, the light control layer LCL may be formed on the display panel DP. For example, the light control layer LCL including the light-blocking members BM, the first refractive layer AL1, and the second refractive layer AL2 may be formed on the display panel DP.

Referring to FIGS. 2, 7, and 12, in an operation S730, the window WIN may be located on the light control layer LCL. Accordingly, the upper surface of the display device DD may be protected from air or dust.

Referring to FIG. 8, the operation S720 may include disposing (e.g., locating or arranging) the light-blocking members to be spaced apart from each other (S810), forming the first refractive layer on the light-blocking members (S820), and disposing the second refractive layer having the refractive index greater than the refractive index of the first refractive layer on the first refractive layer (S830).

Referring to FIGS. 2, 8, and 9, in an operation S810, the light-blocking members BM may be spaced apart from each other. For example, a material including black carbon may be provided to form the light-blocking members BM on the display panel DP. Accordingly, the light-blocking members BM may be located on the display panel DP to be spaced apart from each other in the second direction DR2. The light-blocking members BM of FIG. 8 may be described similarly to the light-blocking members BM of FIGS. 2 and 5.

In this operation, according to embodiments, the light-blocking layer BML may be formed on the light-blocking members BM. For example, the light-blocking layer BML may be located on the side surface of each of the light-blocking members BM. The refractive index of the light-blocking layer BML may be greater than the refractive index of the light-blocking members BM, and may be less than the refractive index of the first refractive layer AL1.

Referring to FIGS. 2, 8, 10, and 11, in an operation S820, the first refractive layer AL1 may be formed on the light-blocking members BM. For example, an inorganic layer for forming the first refractive layer AL1 may be located on the display panel DP and the light-blocking members BM. The inorganic film may include at least one of LiF, MgF, or SiOₙ (n being a natural number of 1 or more).

According to embodiments, the first refractive layer AL1 may be formed on the light-blocking members BM through an evaporation process. However, the method is not limited thereto, as long as the first refractive layer AL1 can be formed on the light-blocking members BM. Accordingly, the first refractive layer AL1 may be formed to have a relatively thin and substantially uniform thickness. The first refractive layer AL1 may include an organic material. For example, the first refractive layer AL1 may be an organic material including acrylate.

Referring to FIG. 11, in this operation, a portion of the first refractive layer AL1 may be removed. For example, the first refractive layer AL1 may be etched, and thus the upper surfaces of the light-blocking members BM may be exposed. However, it is not limited thereto as long as it can expose the upper surface of the light-blocking members BM. The first refractive layer AL1 of FIG. 11 may be described similarly to the first refractive layer AL1 of FIGS. 2 and 5.

Referring to FIGS. 2, 8, and 12, in an operation S730, the second refractive layer AL2, which has the refractive index that is greater than the refractive index of the first refractive layer AL1, may be located on the first refractive layer AL1. Accordingly, one surface of the first refractive layer AL1 may be configured as a total reflection surface with respect to the second refractive layer AL2.

The second refractive layer AL2 may be made of an optically transparent material. For example, the second refractive layer AL2 may be made of a transparent material that can transmit light incident to the light control layer LCL. The second refractive layer AL2 may include an organic material. For example, the second refractive layer AL2 may include acrylic resin.

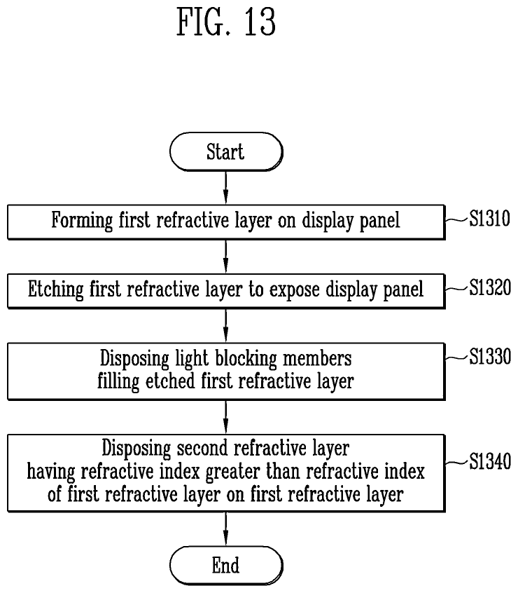

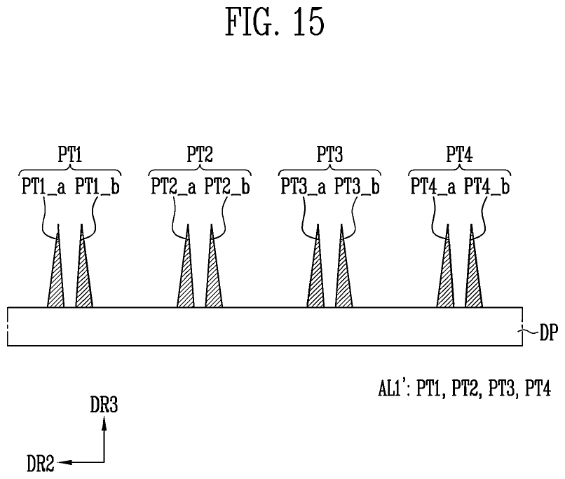

Next, with reference to FIGS. 13 to 16, a manufacturing method of the display device according to one or more embodiments will be described. Duplicate description is briefly explained or not repeated.

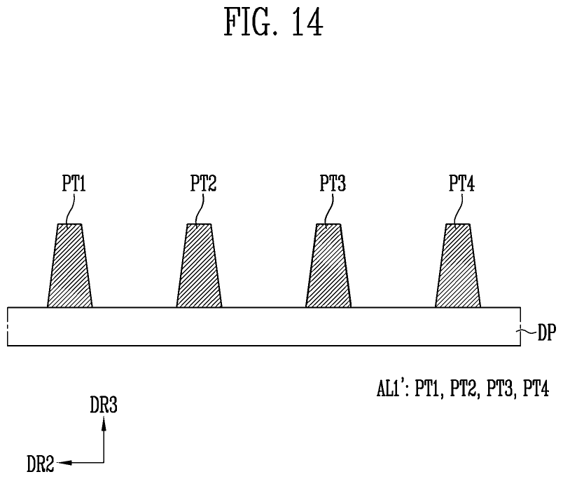

FIG. 13 is a flowchart showing one or more embodiments of an operation S720 of FIG. 7. FIGS. 14 to 16 are schematic cross-sectional views showing each manufacturing operation of a manufacturing method of a display device according to one or more embodiments.

Referring to FIGS. 7, 13, and 14, in an operation S1310, the first refractive layer AL1′ may be formed on the display panel DP. For example, a first refractive layer AL1′ including a plurality of protrusions PT1 to PT4 may be formed on the display panel DP.

The plurality of protrusions PT1 to PT4 may have a trapezoidal shape. For example, the first to fourth protrusions PT1, PT2, PT3, and PT4 may have a trapezoidal shape, and may be spaced apart from each other on the display panel DP in the second direction DR2.

Referring to FIGS. 7, 13, and 15, in an operation S1320, the first refractive layer AL1′ may be etched to expose the display panel DP. For example, central portions of the plurality of protrusions PT1 to PT4 may be etched to expose the upper surface of the display panel DP.

In this operation, each of the plurality of protrusions PT1 to PT4 may include first and second sub-protrusions. For example, the first protrusion PT1 whose central portion is etched may include first and second sub-protrusions PT1_a and PT1_b.

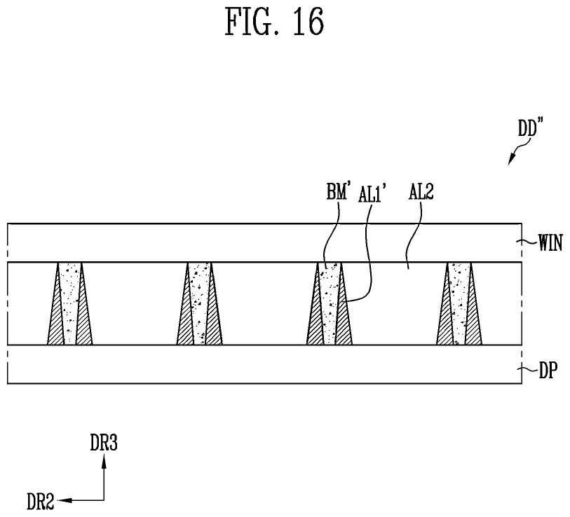

Referring to FIGS. 7, 13, and 16, in an operation S1330, the light-blocking members BM′ filling the etched first refractive layer AL1′ may be located or set. The light-blocking members BM′ may fill the plurality of protrusions PT1 to PT4. For example, the first protrusion PT1 may include a filling space located between the first sub-protrusion PT1_a and the second sub-protrusion PT2_a that are spaced apart from each other. The light-blocking members BM′ may be located on the corresponding filling space. The light-blocking members BM′ of FIG. 16 may be described similarly to the light-blocking members BM′ of FIG. 6.

The light-blocking members BM′ may have an inverted trapezoidal shape. For example, the filling space located between the first sub-protrusion PT1_a and the second sub-protrusion PT2_a may have an inverted trapezoidal shape. Accordingly, the light-blocking members BM′ located in the corresponding filling space may have an inverted trapezoidal shape.

Referring to FIGS. 7, 13, and 16, in an operation S1340, the second refractive layer AL2, which has the refractive index that is greater than the refractive index of the first refractive layer AL1′, may be located on the first refractive layer AL1′. Accordingly, one surface of the first refractive layer AL1′ may be configured as a total reflection surface with respect to the second refractive layer AL2.

Although specific embodiments and applications are described herein, other embodiments and variations may be derived from the above description. Accordingly, the spirit of the present disclosure is not limited to these embodiments but extends to the scope of the claims set forth below, various obvious modifications, and equivalents.

What is claimed is:

1. A display device comprising:
a display panel;
a window above the display panel; and
a light control layer between the display panel and the window, and comprising:
light-blocking members spaced apart from each other;
a first refractive layer on side surfaces of the light-blocking members to expose upper surfaces of the light-blocking members; and
a second refractive layer on the first refractive layer, and having a refractive index that is greater than a refractive index of the first refractive layer.

2. The display device of claim 1, wherein the light-blocking members have a trapezoidal shape in cross section view.

3. The display device of claim 2, wherein an inclination angle between the first refractive layer and a plane on which the display panel is located is about 70 degrees or more and about 89 degrees or less.

4. The display device of claim 3, wherein the inclination angle corresponds to the refractive index of the first refractive layer and to the refractive index of the second refractive layer.

5. The display device of claim 1, wherein the first refractive layer comprises an inorganic material, and
wherein the second refractive layer comprises an organic material.

6. The display device of claim 5, wherein the first refractive layer comprises at least one of LiF or MgF.

7. The display device of claim 1, further comprising a light-blocking layer between one of the light-blocking members and the first refractive layer.

8. The display device of claim 7, wherein a refractive index of the light-blocking layer is greater than a refractive index of the light-blocking members, and is less than the refractive index of the first refractive layer.

9. The display device of claim 1, wherein the light-blocking members have an inverted trapezoidal shape in cross section view.

10. The display device of claim 1, further comprising an input-sensing layer between the display panel and the light control layer.

11. A manufacturing method of a display device comprising:
providing a display panel;
forming a light control layer above the display panel; and
locating a window above the light control layer,
wherein the forming the light control layer comprises:
arranging light-blocking members spaced apart from each other;
forming a first refractive layer on the light-blocking members; and
arranging a second refractive layer, which has a refractive index that is greater than a refractive index of the first refractive layer, on the first refractive layer.

12. The manufacturing method of claim 11, wherein the light-blocking members have a trapezoidal shape in cross section view, and
wherein an inclination angle between the first refractive layer and a plane on which the display panel is located is about 70 degrees or more and about 89 degrees or less.

13. The manufacturing method of claim 11, wherein the forming the light control layer further comprises exposing upper surfaces of the light-blocking members.

14. The manufacturing method of claim 13, wherein exposing the upper surfaces of the light-blocking members comprises an etching process.

15. The manufacturing method of claim 11, wherein forming the first refractive layer comprises an evaporation process, and
wherein the first refractive layer comprises an organic material.

16. The manufacturing method of claim 11, wherein the forming the light control layer further comprises forming a light-blocking layer between one of the light-blocking members and the first refractive layer.

17. The manufacturing method of claim 11, wherein the light-blocking members have an inverted trapezoidal shape in cross section view.

18. A manufacturing method of a display device comprising:
providing a display panel;
forming a light control layer above the display panel; and
arranging a window above the light control layer,
wherein the forming the light control layer comprises:
forming a first refractive layer on the display panel;
etching the first refractive layer to expose the display panel;
arranging light-blocking members filling the etched first refractive layer; and
arranging a second refractive layer, which has a refractive index that is greater than a refractive index of the first refractive layer, on the first refractive layer.

19. The manufacturing method of claim 18, wherein the first refractive layer comprises a plurality of protrusions having a trapezoidal shape.

20. The manufacturing method of claim 19, wherein the light-blocking members have an inverted trapezoidal shape in cross section view.
